(19) United States
(12) Patent Application Publication
(10) Pub. No.: US 2026/0090331 A1
(43) Pub. Date: Mar. 26, 2026

(54) ELECTROSTATIC CHUCK

(71) Applicant: TOTO LTD., Fukuoka (JP)

(72) Inventors: Yuki SASAKI, Fukuoka (JP); Jun SHIRAISHI, Fukuoka (JP); Ikuo ITAKURA, Fukuoka (JP); Shunya MIYAZAKI, Fukuoka (JP)

(73) Assignee: TOTO LTD., Fukuoka (JP)

(21) Appl. No.: 19/284,180

(22) Filed: Jul. 29, 2025

(30) Foreign Application Priority Data
Sep. 24, 2024 (JP) 2024-165031

(51) Int. Cl. H01L 21/683

(52) U.S. Cl. CPC H10P 72/722

(57) ABSTRACT

An electrostatic chuck 10 includes: a dielectric substrate 100 that includes a first part 101 including a surface 110 as a placement surface, and a second part 102 thinner than the first part 101 projecting from an outer peripheral end of the first part 101 further toward an outer peripheral side; a first internal electrode 140 provided inside the first part 101; a second internal electrode 150 provided inside the second part 102; a first power supply member 401 that is provided on a surface 120 of the dielectric substrate 100 and electrically connected to the first internal electrode 140; and a second power supply member 402 that is provided on the surface 120 of the dielectric substrate 100 and electrically connected to the second internal electrode 150. Both of the first power supply member 401 and the second power supply member 402 are provided in the first part 101 of the dielectric substrate 100.

### CROSS-REFERENCE TO RELATED APPLICATION

This application is based upon and claims the benefit of priority from Japanese Patent Application No. 2024-165031 filed on Sep. 24, 2024, the entire contents of which are incorporated herein by reference.

### FIELD

The present invention relates to an electrostatic chuck.

### BACKGROUND

For example, in a semiconductor manufacturing apparatus such as an etching apparatus, an electrostatic chuck is provided as an apparatus configured to adsorb and hold a wafer such as a silicon wafer to be processed. The electrostatic chuck includes a dielectric substrate to which an adsorption electrode is provided and a base plate which supports the dielectric substrate, and has a configuration in which these are joined to each other. When a voltage is applied to the adsorption electrode, an electrostatic force is generated, and the wafer placed on the dielectric substrate is adsorbed and held.

During a process on the wafer, an annular member which is called a focus ring and the like is arranged around the wafer. As disclosed in Japanese Patent Laid-Open No. 2023-177720, a flange section for placing such an annular member may be provided on the dielectric substrate. A part of the dielectric substrate including a placement surface on which a wafer such as a silicon wafer is placed is also referred to as a first part hereinafter. The above-described flange section provided on the dielectric substrate is also referred to as a second part hereinafter. The second part (flange section) is a part that projects from an outer peripheral end of the first part further toward an outer peripheral side, and is thinner than the first part.

### SUMMARY

An internal electrode is provided in each of the first part and the second part. The internal electrode may be provided as an “adsorption electrode” for generating an adsorption force between itself and the wafer or the annular member, or may be provided as an “RF electrode” for generating plasma to be attracted to the wafer side.

Power supply to each internal electrode is performed via a member provided on a surface on an opposite side of the placement surface of the dielectric substrate. Such a member will also be hereinafter referred to as a “power supply member”. The power supply member is, for example, a metallic terminal.

In the electrostatic chuck disclosed in Patent Literature 1 described above, the power supply member provided in the first part is connected to the internal electrode of the first part, and the power supply member provided in the second part is connected to the internal electrode of the second part.

However, the second part is a relatively thin part of the dielectric substrate, so that it is difficult to provide the power supply member in the second part in many cases. Particularly, the dielectric substrate tends to be made thinner in recent years, so that it will be more difficult to provide the power supply member in the second part.

The present invention has been made in view of such an issue and is aimed to provide an electrostatic chuck in which a power supply member connected to an internal electrode of a flange section can be easily provided.

To solve the above-described issue, the electrostatic chuck according to the present invention includes: a dielectric substrate that includes a first part including a placement surface on which an object to be adsorbed is placed, and a second part that projects from an outer peripheral end of the first part further toward an outer peripheral side, and is thinner than the first part; a first internal electrode provided inside the first part; a second internal electrode provided inside the second part; a first power supply member that is provided on a surface on an opposite side of the placement surface in the dielectric substrate, and electrically connected to the first internal electrode; and a second power supply member that is provided on a surface on an opposite side of the placement surface in the dielectric substrate, and electrically connected to the second internal electrode, and both of the first power supply member and the second power supply member are provided in the first part of the dielectric substrate.

In the electrostatic chuck having the above-described configuration, the second power supply member electrically connected to the second internal electrode of the second part (flange section) is not provided in the second part but is provided in the first part. The first part is a part thicker than the second part, so that both of the first power supply member and the second power supply member can be easily provided therein.

According to the present invention, it is possible to provide the electrostatic chuck in which the power supply member connected to the internal electrode of the flange section can be easily provided.

### BRIEF DESCRIPTION OF THE DRAWINGS

FIG. 1 is a cross-sectional view schematically illustrating a configuration of an electrostatic chuck according to the present embodiment;

FIG. 2 is a perspective view illustrating a configuration of a power supply member;

FIG. 3 is a diagram illustrating a configuration of a second internal electrode and the like;

FIG. 4 is a diagram for explaining arrangement of a gas hole and the power supply member; and

FIG. 5 is a diagram for explaining arrangement of the gas hole, the power supply member, a distribution flow path, and a seal ring.

### DETAILED DESCRIPTION

Hereinafter, the present embodiment will be described with reference to the accompanying drawings. To ease understanding of the descriptions, in each drawing, the same components are denoted by the same reference signs as much as possible, and duplicate descriptions are not repeated.

An electrostatic chuck 10 according to the present embodiment is configured to adsorb and hold a wafer W set as a process target by an electrostatic force inside a semiconductor manufacturing apparatus such as, for example, an etching apparatus which is not illustrated in the drawing. The wafer W that is an object to be adsorbed is, for example, a silicon wafer. The electrostatic chuck 10 may be used in an apparatus other than the semiconductor manufacturing apparatus.

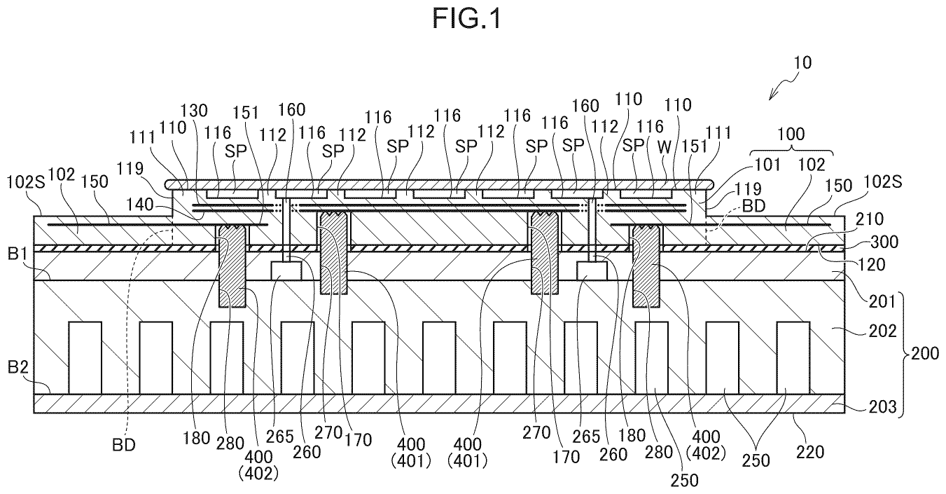

FIG. 1 is a cross sectional view schematically illustrating a configuration of the electrostatic chuck 10 in a state in which the wafer W is adsorbed and held. The electrostatic chuck 10 includes a dielectric substrate 100 and a base plate 200.

The dielectric substrate 100 is a substantially disk-shaped member formed of a ceramic sintered body. The dielectric substrate 100 contains, for example, highly pure aluminum oxide (Al₂O₃), but may contain other materials. A ceramics purity or type, an additive, or the like in the dielectric substrate 100 may be appropriately set by taking into account plasma resistance or the like needed for the dielectric substrate 100 in the semiconductor manufacturing apparatus.

A surface 110 on an upper side in FIG. 1 in the dielectric substrate 100 serves as a “placement surface” on which the wafer W is placed. A surface 120 on a lower side in FIG. 1 in the dielectric substrate 100 serves as a “surface to be joined” which is joined to the base plate 200 via a joining layer 300. A perspective in a case where the electrostatic chuck 10 is viewed from the surface 110 side along a direction perpendicular to the surface 110 will also be hereinafter expressed as “top view”.

The dielectric substrate 100 includes a first part 101 and a second part 102. The first part 101 is a substantially cylindrical part extending from the surface 110 toward the lower side in FIG. 1 up to a surface 120. It can be said that the first part 101 as described above is a part including the surface 110 as the placement surface in the dielectric substrate 100.

The second part 102 is an annular part projecting from an outer peripheral end of the first part 101 further toward an outer peripheral side, which is also referred to as a “flange section” of the dielectric substrate 100. In FIG. 1, a dotted line denoted by reference sign “BD” represents a boundary between the first part 101 and the second part 102. This boundary will also be hereinafter referred to as a “boundary BD”. In top view, the boundary BD is present at a position that completely overlaps with an outer surface 119 of the first part 101.

The second part 102 is thinner than the first part 101. The surface 120 described above is a surface on the lowermost side of the first part 101 in FIG. 1, and is also a surface on the lowermost side of the second part 102. A surface 102S on the uppermost side of the second part 102 is present at a position lower than the surface 110 in FIG. 1.

When a process on the wafer W is to be performed in the semiconductor manufacturing apparatus, an annular member which is referred to as a “focus ring” and the like and not illustrated in the drawing is arranged around the wafer W. The surface 102S of the second part 102 is a part that supports such an annular member from the lower side. The surface 102S is a surface parallel to the surface 110.

An adsorption electrode 130 is provided inside the first part 101 of the dielectric substrate 100. The adsorption electrode 130 is a thin planar layer made of a metallic material such as, for example, tungsten, and is arranged so as to be parallel to the surface 110. As a material of the adsorption electrode 130, molybdenum, platinum, palladium, and the like may be used in addition to tungsten. When a voltage is applied to the adsorption electrode 130 from an outside via a feed line which is not illustrated in the drawing, an electrostatic force is generated between the surface 110 and the wafer W, and according to this, the wafer W is adsorbed and held. As a configuration of the above-described feed line, various configurations in related art can be adopted. The single adsorption electrode 130 may be provided as so-called a “monopolar” electrode as in the present embodiment, but may also include two adsorption electrodes as so-called “bipolar” electrodes.

In addition to the above-described adsorption electrode 130, a first internal electrode 140 is embedded inside the first part 101. The first internal electrode 140 is provided as one of a pair of counter electrodes configured to generate plasma in a semiconductor manufacturing apparatus. The other of the counter electrodes is provided at a position on an upper side of the electrostatic chuck 10 in the semiconductor manufacturing apparatus. When high-frequency alternating-current voltage is applied between these counter electrodes, plasma is generated on the upper side of the wafer W and used for processing such as film deposition and etching on the wafer W. The first internal electrode 140 is also referred to as an “RF electrode” and the like.

Similarly to the adsorption electrode 130, the first internal electrode 140 is a thin planar layer made of a metallic material such as tungsten, for example. As a material of the first internal electrode 140, molybdenum, platinum, palladium, and the like may be used in addition to tungsten. The first internal electrode 140 is embedded at a position on the surface 120 side than the adsorption electrode 130. Similarly to the adsorption electrode 130, the first internal electrode 140 is disposed in parallel to the surface 110. The first internal electrode 140 is a single electrode which is substantially circular in top view. In top view, a center of the first internal electrode 140 matches a center of the dielectric substrate 100.

The first internal electrode 140 is electrically connected to the base plate 200 via a first power supply member 401 described later. Power supply to the first internal electrode 140 is performed via the base plate 200 and the first power supply member 401.

A second internal electrode 150 is provided inside the second part 102 of the dielectric substrate 100. The second internal electrode 150 is provided as one of the pair of counter electrodes configured to generate plasma in the semiconductor manufacturing apparatus together with the first internal electrode 140 described above, and is also referred to as an “RF electrode” and the like.

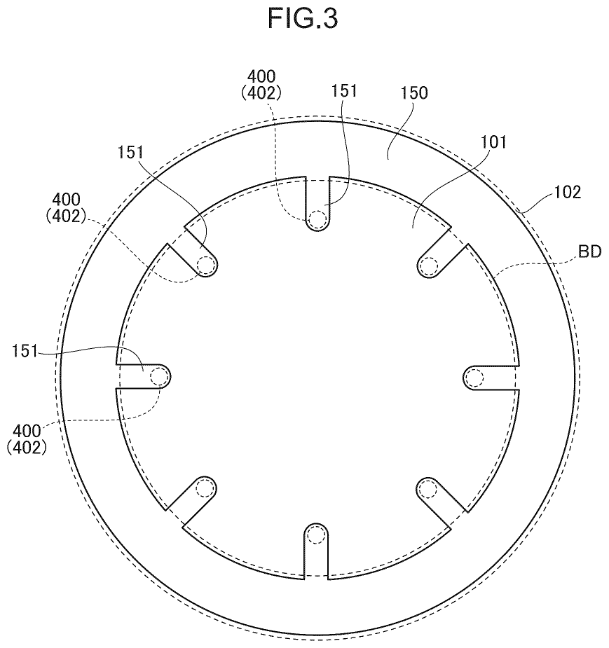

The second internal electrode 150 is a thin planar layer made of a material similar to that of the adsorption electrode 130 or the first internal electrode 140, and is arranged so as to be parallel to the surface 110 and the surface 102S. The second internal electrode 150 is a single electrode which is substantially annular in top view as illustrated in FIG. 3. In top view, a center of the second internal electrode 150 matches the center of the dielectric substrate 100.

The second internal electrode 150 is electrically connected to the base plate 200 via a second power supply member 402 described later. Power supply to the second internal electrode 150 is performed via the base plate 200 and the second power supply member 402.

The description will be continued returning to FIG. 1. A space SP is formed between the dielectric substrate 100 and the wafer W. When a process such as etching is performed in the semiconductor manufacturing apparatus, a helium gas for temperature regulation is supplied to the space SP from the outside via a gas hole 160 or the like described later. When the helium gas is caused to be present between the dielectric substrate 100 and the wafer W, a thermal resistance between the dielectric substrate 100 and the wafer W is regulated, and according to this, a temperature of the wafer W is maintained at an appropriate temperature. It is noted that the gas for temperature regulation to be supplied to the space SP may be a gas of a type different from helium.

A seal ring 111 and a dot 112 are provided on the surface 110 which serves as the placement surface, and the space SP described above is formed around the seal ring 111 and the dot 112.

The seal ring 111 is an annular protrusion provided at a position corresponding to an outermost circumference of the first part 101 so as to define the space SP. An upper end of the seal ring 111 becomes a part of the surface 110 and abuts against the wafer W. It is noted that the seal ring 111 may include a plurality of seal rings 111 provided so as to divide the space SP. With such a configuration, a pressure of the helium gas in each of the spaces SP can be individually regulated, and a surface temperature distribution of the wafer W during the process can be set to be close to uniformity.

A part denoted by reference sign “116” in FIG. 1 is a bottom of the space SP. Hereinafter, this part may also be referred to as a “bottom 116”. The seal ring 111 is formed as a result of digging a part of the surface 110 to a position of the bottom 116 together with the dot 112 which will be described next.

The dot 112 is a circular protrusion which protrudes from the bottom 116. The dot 112 includes a plurality of dots 112 to be provided. The plurality of dots 112 are substantially uniformly distributed and arranged on the placement surface of the dielectric substrate 100. An upper end of each of the dots 112 becomes a part of the surface 110 and abuts against the wafer W. By providing the plurality of thus configured dots 112, warping of the wafer W is reduced.

The gas hole 160 is formed in the dielectric substrate 100. The gas hole 160 is a through hole formed so as to extend in a direction perpendicular to the surface 110 serving as the placement surface. An end on the surface 110 side of the gas hole 160 is connected to the space SP. The gas hole 160 is a part of a flow path for supplying a helium gas toward the space SP. The gas hole 160 includes a plurality of gas holes 160 which are formed in the dielectric substrate 100, but FIG. 1 illustrates only two of the gas holes 160.

An inner diameter of the gas hole 160 is uniform throughout the entirety, but the inner diameter may vary in some parts. For example, the diameter of the gas hole 160 on the surface 120 side may be increased, and a porous member configured to prevent an electric discharge may be arranged inside the part where the diameter is increased.

The base plate 200 is a substantially disk-shaped member which supports the dielectric substrate 100. The base plate 200 is made of, for example, a metallic material such as aluminum. A surface 210 on the upper side in FIG. 1 in the base plate 200 serves as a “surface to be joined” which is joined to the dielectric substrate 100 via the joining layer 300. An outer shape of the surface 210 in top view is substantially the same as an outer shape of the second part 102 in top view.

The joining layer 300 is a layer provided between the dielectric substrate 100 and the base plate 200 to join those components. The joining layer 300 is provided by causing an adhesive made of an insulating material to be cured. According to the present embodiment, a silicone adhesive is used as the above-described adhesive. It is noted however that the joining layer 300 may be provided by causing an adhesive made of other types to be cured. In any case, in order that a thermal resistance between the dielectric substrate 100 and the base plate 200 is reduced, a material with a highest possible thermal conductivity may be used as the material of the joining layer 300.

An insulating film may be formed on a surface of the base plate 200. As the insulating film, for example, an alumina film formed by thermal splaying can be used. When the surface of the base plate 200 is covered by the insulating film, a withstand voltage of the base plate 200 may be increased.

A coolant flow path 250 through which a coolant flows is formed inside the base plate 200. When the process such as etching is performed in the semiconductor manufacturing apparatus, the coolant is supplied from the outside to the coolant flow path 250, and according to this, the base plate 200 is cooled down. Heat generated in the wafer W during the process is transferred to the coolant via the helium gas in the space SP, the dielectric substrate 100, and the base plate 200, and the heat is exhausted to the outside together with the coolant. The supply and exhaustion of the coolant to and from the coolant flow path 250 are performed via openings which are not illustrated in the drawing and which are formed in a surface 220 opposite to the surface 210 in the base plate 200. The coolant flow path 250 is formed to pass through not only a range overlapping with the first part 101 in top view but also a range overlapping with the second part 102. Due to this, an annular member placed on the surface 102S is also cooled down by the coolant passing through the coolant flow path 250.

Gas holes 260 are formed in the base plate 200. The gas hole 260 is a hole formed so as to extend in a direction perpendicular to the surface 110 serving as the placement surface. The gas hole 260 extends from the surface 210 up to a distribution flow path 265 which will be described below. The gas holes 260 are formed at respective positions that overlap with the gas holes 160 in top view, and communicates with the gas holes 160 via through holes provided in the joining layer 300. The gas hole 260 serves as a part of the flow path for supplying the helium gas toward the space SP on the placement surface side together with the gas hole 160 of the dielectric substrate 100.

An inner diameter of the gas hole 260 is uniform throughout the entirety, but the inner diameter may vary in some parts. For example, the diameter of the gas hole 260 on the surface 210 side may be increased, and a porous member configured to prevent an electric discharge may be arranged inside the part where the diameter is increased.

Distribution flow paths 265 are formed inside the base plate 200. The distribution flow path 265 is a flow path for distributing the helium gas to each of the gas holes 260. The distribution flow path 265 is routed in parallel to the surface 210 and connected to a lower end of each of the gas holes 260.

The helium gas supplied from the outside flows into the distribution flow paths 265 through a flow path which is formed inside the base plate 200 and not illustrated in the drawing, and is distributed to the respective gas holes 260 from the distribution flow paths 265. By forming the distribution flow paths 265 inside the base plate 200, the number of parts where the helium gas is supplied from the outside can be reduced.

In this manner, the coolant flow path 250, the distribution flow path 265, the gas hole 260, and the like are formed inside the base plate 200, and the base plate 200 has the relatively complex inner structure. To facilitate the formation of the coolant flow path 250 and the like, the base plate 200 of the present embodiment is formed by joining a plurality of members to each other. Specifically, the base plate 200 is formed by mutually joining three members including a first member 201, a second member 202, and a third member 203 to be integrated. Each member is joined by welding, but for example, each member may be joined by a method such as brazing or fastening and fixing. The number of members constituting the base plate 200 may be four or more or may be two.

The first member 201, the second member 202, and the third member 203 are aligned in the stated order along the direction perpendicular to the surface 110 serving as the placement surface. The first member 201 is a part closest to the dielectric substrate 100 among the members constituting the base plate 200. The surface 210 described above is a part of the first member 201. The third member 203 is a part on an opposite side of the dielectric substrate 100 among the members constituting the base plate 200. The surface 220 described above is a part of the third member 203. The second member 202 is a member located between the first member 201 and the third member 203.

A joint boundary B1 between the first member 201 and the second member 202 is parallel to the surface 110 and the surface 210. A joint boundary B2 between the second member 202 and the third member 203 is also parallel to the surface 110 and the surface 210.

Both the distribution flow path 265 and the gas hole 260 according to the present embodiment are entirely formed in the first member 201. The distribution flow path 265 is an annular groove which has been formed in advance along a front surface serving as the joint boundary B1 in the first member 201 before each member is joined. In this manner, by forming the groove in the front surface of the first member 201 in advance and joining the second member 202 so as to cover the front surface, the distribution flow path 265 along the groove can be easily formed inside the base plate 200. It is noted that the groove serving as the distribution flow path 265 may be formed in a front surface serving as the joint boundary B1 in the second member 202 instead of the front surface of the first member 201.

As illustrated in FIG. 1, the coolant flow path 250 according to the present embodiment is entirely formed in the second member 202. The coolant flow path 250 is a groove which has been formed in advance along a front surface serving as the joint boundary B2 in the second member 202 before each member is joined. In this manner, by forming the groove in the front surface of the second member 202 in advance and joining the third member 203 so as to cover the front surface, the coolant flow path 250 along the groove can be easily formed inside the base plate 200. It is noted that the groove serving as the coolant flow path 250 may be formed in a front surface serving as the joint boundary B1 in the second member 202.

As described above, the first internal electrode 140 and the second internal electrode 150 provided inside the dielectric substrate 100 both function as RF electrodes, and are electrically connected to the base plate 200. The first internal electrode 140 and the base plate 200 are electrically connected to each other via the first power supply member 401. The second internal electrode 150 and the base plate 200 are electrically connected to each other via the second power supply member 402.

A recessed section 170 is formed in the surface 120 on the base plate 200 side of the dielectric substrate 100. The recessed section 170 is a part obtained by causing a part of the surface 120 to retreat toward the surface 110 in a recessed shape to enable the first power supply member 401 to be arranged. The first internal electrode 140 is exposed at a bottom of the recessed section 170. A shape of the recessed section 170 in top view is circular, and a space of a substantially cylindrical shape is formed on an inner side of the recessed section 170.

A recessed section 270 is formed in the surface 210 on the dielectric substrate 100 side of the base plate 200. The recessed section 270 is formed in a portion that overlaps with the recessed section 170 in the surface 210 in top view. The recessed section 270 is a part obtained by causing a part of the surface 210 to retreat toward the surface 220 in a recessed shape to enable the first power supply member 401 to be arranged. A metallic part of the base plate 200 is exposed on an inner side of the recessed section 270 throughout the entirety. A shape of the recessed section 270 in top view is circular, and a space of a substantially cylindrical shape is formed on an inner side of the recessed section 270. A central axis of the recessed section 270 matches a central axis of the recessed section 170. A lower end of the recessed section 270 in FIG. 1 is present at a position further on a lower side of a lower end of the distribution flow path 265.

A circular opening is formed in a part between the recessed section 170 and the recessed section 270 in the joining layer 300. The recessed section 170 and the recessed section 270 are connected to each other via the opening, and a whole of these becomes one space. The first power supply member 401 is housed inside the recessed section 170 and the recessed section 270.

The first power supply member 401 abuts against the first internal electrode 140 exposed at the bottom of the recessed section 170. The first power supply member 401 also abuts against the metallic part of the base plate 200 which is exposed at a bottom of the recessed section 270. The first internal electrode 140 and the metallic part of the base plate 200 are electrically connected to each other by the thus arranged first power supply member 401. The first power supply member 401 includes a plurality of first power supply members 401 which are provided on the surface 120 of the dielectric substrate 100, but FIG. 1 illustrates only two of the first power supply members 401.

A recessed section 180 is formed in the surface 120 on the base plate 200 side of the dielectric substrate 100. The recessed section 180 is a part obtained by causing a part of the surface 120 to retreat toward the surface 110 in a recessed shape to enable the second power supply member 402 to be arranged. A connection section 151 connected to the second internal electrode 150 is exposed at a bottom of the recessed section 180. The connection section 151 will be described later. A shape of the recessed section 180 in top view is circular, and a space of a substantially cylindrical shape is formed on an inner side of the recessed section 180.

A recessed section 280 is formed in the surface 210 on the dielectric substrate 100 side of the base plate 200. The recessed section 280 is formed in a portion that overlaps with the recessed section 180 in the surface 210 in top view. The recessed section 280 is a part obtained by causing a part of the surface 210 to retreat toward the surface 220 in a recessed shape to enable the second power supply member 402 to be arranged. A metallic part of the base plate 200 is exposed on an inner side of the recessed section 280 throughout the entirety. A shape of the recessed section 280 in top view is circular, and a space of a substantially cylindrical shape is formed on an inner side of the recessed section 280. A central axis of the recessed section 280 matches a central axis of the recessed section 180. A lower end of the recessed section 280 in FIG. 1 is present at a position further on a lower side of the lower end of the distribution flow path 265.

A circular opening is formed in a part between the recessed section 180 and the recessed section 280 in the joining layer 300. The recessed section 180 and the recessed section 280 are connected to each other via the opening, and a whole of these becomes one space. The second power supply member 402 is housed inside the recessed section 180 and the recessed section 280.

The second power supply member 402 abuts against the connection section 151 exposed at the bottom of the recessed section 180. The second power supply member 402 also abuts against the metallic part of the base plate 200 which is exposed at a bottom of the recessed section 280. The second internal electrode 150 and the metallic part of the base plate 200 are electrically connected to each other by the thus arranged second power supply member 402. The second power supply member 402 includes a plurality of second power supply members 402 which are provided on the surface 120 of the dielectric substrate 100, but FIG. 1 illustrates only two of the second power supply members 402.

Due to the first power supply member 401, a potential of the first internal electrode 140 during the process on the wafer W becomes the same as a potential of the base plate 200. Similarly, due to the second power supply member 402, a potential of the second internal electrode 150 during the process on the wafer W becomes the same as the potential of the base plate 200. The first power supply member 401 and the second power supply member 402 have the same shape. They are also collectively referred to as a “power supply member 400” hereinafter. The power supply member 400 is a member of a substantially cylindrical shape made of a fibrous metal member.

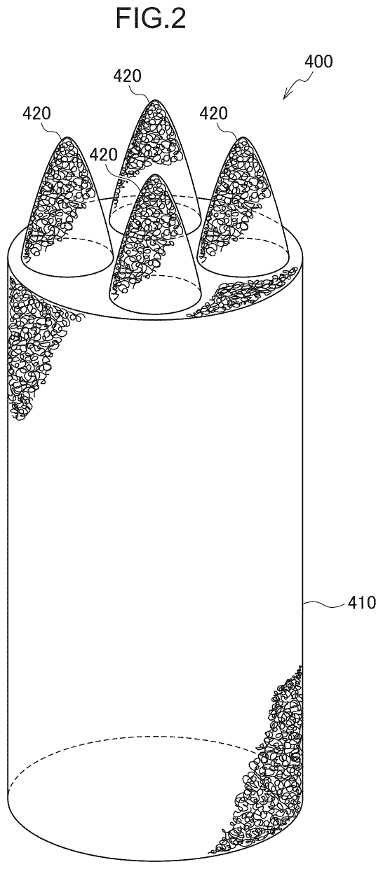

As illustrated in FIG. 2, the power supply member 400 includes a main body section 410 of a substantially cylindrical shape and a plurality of protrusion sections 420, and an entirety thereof is integrally formed of the fibrous metal member. The protrusion section 420 is a protrusion of a substantially cylindrical shape which is formed so as to extend from the surface on the dielectric substrate 100 side in the main body section 410 further towards the dielectric substrate 100. According to the present embodiment, four in total of the protrusion sections 420 are formed, but the number of the protrusion sections 420 may be different from four.

The power supply member 400 formed of the fibrous metal member has a breathability to such an extent that allows a fluid such as air to intrude into the inside of the power supply member 400. That is, the fibrous metal member is not sufficiently dense, and there is a gap between mutual fibers. When such a configuration is adopted, the power supply member 400 serves as an elastic body in which each section including the protrusion section 420 may be easily deformed by an external force.

A dimension in an up and down direction (direction in which the protrusion section 420 extends) of the power supply member 400 when the external force is not received is larger than a dimension in the same direction in the state of FIG. 2. That is, the power supply member 400 is housed inside the recessed section 170 or the recessed section 180 in a state of being compressed along a direction from the dielectric substrate 100 toward the base plate 200. A distal end of each of the protrusion sections 420 is elastically deformed so as to collapse by being pressed against the first internal electrode 140 or the connection section 151.

The power supply member 400 is in a state of being pressed against the first internal electrode 140 or the like by its own restoring force. For this reason, during the process on the wafer W or the like, even when thermal expansion or contraction occurs in each section of the electrostatic chuck 10, the electrical connection between the first internal electrode 140 and the base plate 200 and the electrical connection between the second internal electrode 150 and the base plate 200 are regularly maintained. A shape of the power supply member 400 may be different from the shape illustrated in FIG. 2.

FIG. 3 schematically illustrates configurations and the like of the second internal electrode 150 and the connection section 151 connected thereto in top view. The second internal electrode 150 is entirely provided inside the second part 102. On the other hand, the second power supply member 402 for performing power supply to the second internal electrode 150 is provided inside the first part 101 instead of the second part 102. The second internal electrode 150 and the second power supply member 402 are electrically connected to each other via the connection section 151.

The connection section 151 extends in a linear shape from an end on an inner peripheral side of the second internal electrode 150 toward the second power supply member 402 on a more inner peripheral side. The connection section 151 is present at the same height position as the second internal electrode 150, and is parallel to the second internal electrode 150. The connection section 151 is made of the same material as that of the second internal electrode 150, and formed as an electrode layer integrated with the second internal electrode 150. The number of connection sections 151 is the same as the number of second power supply members 402. As described above, an upper end of the second power supply member 402 abuts against each of the connection sections 151.

As described above, the electrostatic chuck 10 according to the present embodiment includes the first power supply member 401 electrically connected to the first internal electrode 140 and the second power supply member 402 electrically connected to the second internal electrode 150, and both of the first power supply member 401 and the second power supply member 402 are provided in the first part 101 of the dielectric substrate 100.

The second internal electrode 150 is provided inside the second part 102, so that it may be considered that the second power supply member 402 connected thereto may be provided in the second part 102. However, the second part 102 is a relatively thin part of the dielectric substrate 100, so that it is difficult to provide the second power supply member 402 in the second part 102 in many cases. Particularly, the dielectric substrate 100 tends to be made thinner in recent years, so that it will be more difficult to provide the second power supply member 402 in the second part 102.

Thus, in the electrostatic chuck 10 according to the present embodiment, both of the first power supply member 401 and the second power supply member 402 are provided in the first part 101. The first part 101 is a part thicker than the second part 102, so that both of the first power supply member 401 and the second power supply member 402 can be easily provided therein.

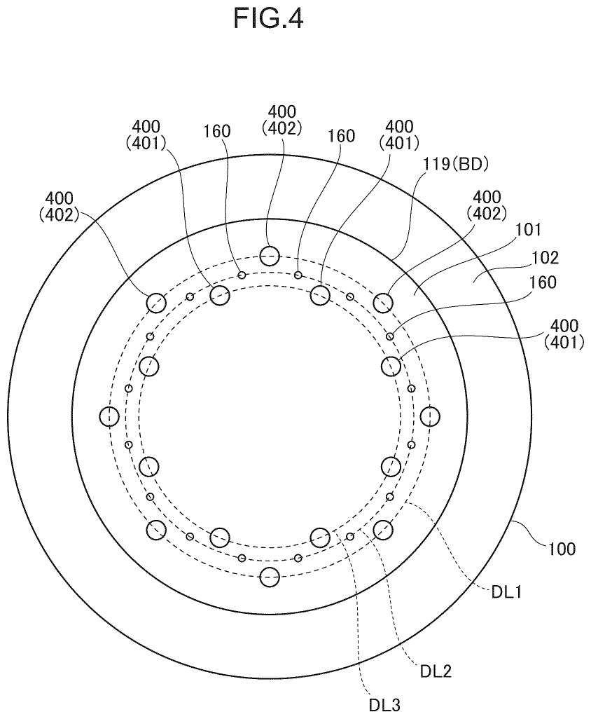

FIG. 4 illustrates arrangement of the gas hole 160, the first power supply member 401, and the second power supply member 402 in the dielectric substrate 100 in top view. The plurality of them are provided, and arranged to be aligned in an annular shape along a circumferential direction.

A dotted line DL1 illustrated in FIG. 4 is a virtual circle which is depicted to pass through centers of all of the second power supply members 402. In top view, a center of the circle of the dotted line DL1 matches a center of the first part 101. The second power supply members 402 are arranged to be aligned in an annular shape at regular intervals along the dotted line DL1.

When the process on the wafer W is performed, Joule heat is generated in the second power supply member 402. That is, the second power supply member 402 becomes a heat generating source. In the present embodiment, by aligning the second power supply members 402 as heat generating sources in an annular shape, variation in an in-plane temperature distribution of the wafer W is suppressed.

As a result of arranging all of the second power supply members 402 along the dotted line DL1, lengths of the connection sections 151 along a radial direction are the same in all of the connection section 151. In such a configuration, magnitude of the Joule heat generated in the second power supply member 402 and the connection section 151 becomes uniform over the entire circumference, so that variation in the in-plane temperature distribution of the wafer W can be further suppressed.

A dotted line DL2 illustrated in FIG. 4 is a virtual circle which is depicted to pass through centers of all of the gas holes 160. In top view, a center of the circle of the dotted line DL2 matches the center of the first part 101. A diameter of the circle of the dotted line DL2 is smaller than a diameter of the circle of the dotted line DL1. The gas holes 160 are arranged to be aligned in an annular shape at regular intervals along the dotted line DL2.

In the vicinity of the gas hole 160, the wafer W is cooled down due to influence of the supplied helium gas. That is, the gas hole 160 becomes a cooling source. In the present embodiment, by aligning the gas holes 160 as cooling sources in an annular shape, variation in the in-plane temperature distribution of the wafer W is further suppressed.

A dotted line DL3 illustrated in FIG. 4 is a virtual circle which is depicted to pass through centers of all of the first power supply members 401. In top view, a center of the circle of the dotted line DL3 matches the center of the first part 101. A diameter of the circle of the dotted line DL3 is further smaller than the diameter of the circle of the dotted line DL2. The first power supply members 401 are arranged to be aligned in an annular shape at regular intervals along the dotted line DL3.

When the process on the wafer W is performed, similarly to the second power supply member 402, Joule heat is also generated in the first power supply member 401. That is, the first power supply member 401 also becomes a heat generating source. In the present embodiment, by aligning the first power supply members 401 as heat generating sources in an annular shape, variation in the in-plane temperature distribution of the wafer W is further suppressed.

The plurality of second power supply members 402 are arranged at positions on the outer peripheral side than the plurality of first power supply members 401. In such a configuration, each of the connection sections 151 becomes short and electric resistance thereof becomes small, so that power efficiency can be enhanced.

The plurality of first power supply members 401 are arranged at positions on the inner peripheral side than the plurality of gas holes 160, and the plurality of second power supply members 402 are arranged at positions on the outer peripheral side than the plurality of gas holes 160. By arranging the gas hole 160 as a cooling source at a position between the first power supply member 401 and the second power supply member 402 as heat generating sources, an excessive temperature rise in the wafer W can be prevented.

In a case where the length of the connection section 151 (and electric resistance caused thereby) is not an issue, positions of the first power supply member 401 and the second power supply member 402 may be replaced with each other. That is, an aspect may be such that the plurality of first power supply members 401 are arranged at positions on the outer peripheral side than the plurality of gas holes 160, and the plurality of second power supply members 402 are arranged at positions on the inner peripheral side than the plurality of gas holes 160.

In the present embodiment, the first power supply member 401, the gas hole 160, the second power supply member 402, and the gas hole 160 are repeatedly arranged in this order along the circumferential direction. By alternatively arranging the heating source and the cooling source along the circumferential direction, a local temperature rise in the wafer W can be suppressed.

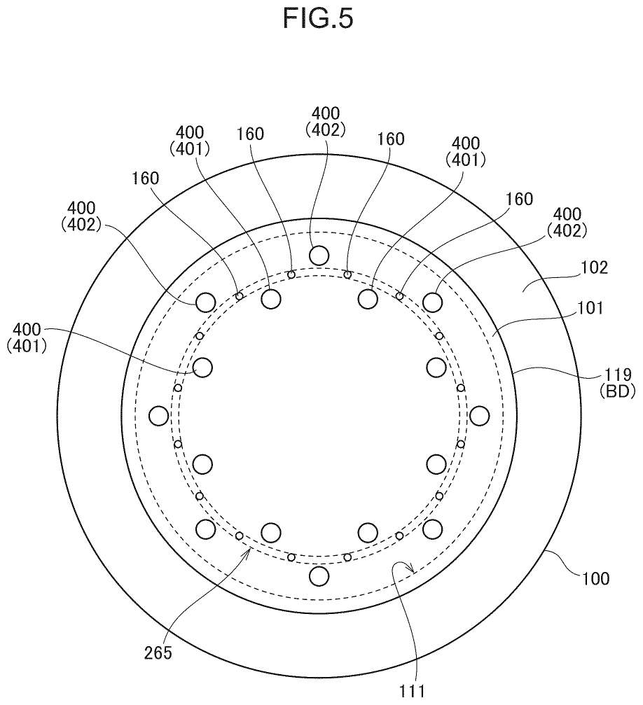

FIG. 5 illustrates arrangement of the gas hole 160, the first power supply member 401, and the second power supply member 402 in the dielectric substrate 100 in top view similarly to FIG. 4. FIG. 5 further illustrates arrangement of the distribution flow path 265 and the seal ring 111.

As illustrated in FIG. 5, both of the first power supply member 401 and the second power supply member 402 in the present embodiment are formed at positions that do not overlap with the distribution flow path 265 in top view. That is, the distribution flow path 265 is arranged so as to avoid a part immediately below the first power supply member 401 and the second power supply member 402 as heat generating sources. In such a configuration, heat dissipation from the first power supply member 401 and the like is not hindered by the distribution flow path 265. Due to this, an excessive temperature rise in the wafer W can be suppressed.

Both of the first power supply member 401 and the second power supply member 402 in the present embodiment are arranged at positions that do not overlap with the seal ring 111 in top view. In such a configuration, heat from the first power supply member 401 or the like as a heat generating source is not directly transmitted to the wafer W via the seal ring 111. Due to this, an excessive temperature rise in the wafer W can be suppressed. In a case where a different seal ring is further provided on the inner peripheral side of the seal ring 111, each of the first power supply member 401 and the second power supply member 402 may be arranged at a position that does not overlap with any of the seal rings in top view.

Both of the first power supply member 401 and the second power supply member 402 in the present embodiment are provided as members for electrically connecting the first internal electrode 140 and the like with the base plate 200. Instead of such an aspect, it is possible to adopt an aspect such that the first power supply member 401 and the second power supply member 402 are electrically connected to an external power source instead of the base plate 200. The second internal electrode 150 provided in the second part 102 may be an RF electrode as in the present embodiment, but may also be an adsorption electrode for attracting an annular member.

The present embodiment has been described above with reference to the specific examples. However, the present disclosure is not limited to these specific examples. Configurations obtained by adding appropriate design modifications to these specific examples by a person skilled in the art are also within the scope of the present disclosure as long as the configurations have a feature of the present disclosure. Each of the elements included in each of the specific examples described above and arrangements, conditions, shapes, and the like of the elements are not limited to those illustrated and can be modified as appropriate. For each of the elements included in each of the specific examples described above, a combination can be appropriately changed as long as a technical contradiction does not occur.

What is claimed is:

1. An electrostatic chuck comprising:
a dielectric substrate that includes a first part including a placement surface on which an object to be adsorbed is placed, and a second part thinner than the first part projecting from an outer peripheral end of the first part further toward an outer peripheral side;
a first internal electrode provided inside the first part;
a second internal electrode provided inside the second part;
a first power supply member that is provided on a surface on an opposite side of the placement surface in the dielectric substrate, and is electrically connected to the first internal electrode; and
a second power supply member that is provided on a surface on an opposite side of the placement surface in the dielectric substrate, and is electrically connected to the second internal electrode, wherein
both of the first power supply member and the second power supply member are provided in the first part of the dielectric substrate.

2. The electrostatic chuck according to claim 1, wherein a plurality of the second power supply members are provided, and are arranged to be aligned in an annular shape along a circumferential direction.

3. The electrostatic chuck according to claim 2, wherein a plurality of the first power supply members are provided, and are arranged to be aligned in an annular shape along the circumferential direction.

4. The electrostatic chuck according to claim 3, wherein the plurality of second power supply members are arranged at positions on an outer peripheral side than the plurality of first power supply members.

5. The electrostatic chuck according to claim 3, wherein a plurality of gas holes are formed in the dielectric substrate, and the plurality of gas holes are arranged to be aligned in an annular shape along the circumferential direction.

6. The electrostatic chuck according to claim 5, wherein
one group of the plurality of first power supply members and the plurality of second power supply members is arranged at positions on an inner peripheral side than the plurality of gas holes, and
the other group of the plurality of first power supply members and the plurality of second power supply members is arranged at positions on an outer peripheral side than the plurality of gas holes.

7. The electrostatic chuck according to claim 5, wherein the first power supply member, the gas hole, the second power supply member, and the gas hole are repeatedly arranged in this order along the circumferential direction.

8. The electrostatic chuck according to claim 1, wherein
a plurality of gas holes are formed in the dielectric substrate, and
when viewed from a direction perpendicular to the placement surface,
the first power supply member and the second power supply member are formed at positions that do not overlap with distribution flow paths for distributing gas to the respective gas holes.

9. The electrostatic chuck according to claim 1, wherein
a seal ring that is an annular protrusion having a distal end surface as a part of the placement surface is provided in the first part, and
when viewed from a direction perpendicular to the placement surface,
the first power supply member and the second power supply member are arranged at positions that do not overlap with the seal ring.

10. The electrostatic chuck according to claim 1, further comprising:
a base plate as a metal member configured to support the dielectric substrate, wherein
both of the first power supply member and the second power supply member are electrically connected to the base plate.
